(19) United States
(12) Patent Application Publication
(10) Pub. No.: US 2007/0090405 A1
(43) Pub. Date: Apr. 26, 2007

(54) Charge compensated dielectric layer structure and method of making the same

(76) Inventors: Matthias Passlack, Chandler, AZ (US); Ravindranath Droopad, Chandler, AZ (US); Karthik Rajagopalan, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/236,187

(22) Filed: Sep. 27, 2005

(51) Int. Cl. H01L 23/58

(52) U.S. Cl. 257/212

(57) ABSTRACT

A method of forming a semiconductor structure comprises providing an insulator layer overlying a III-V compound substrate, the insulator layer having a surface charge layer, the surface charge layer having a deleterious performance effect on the underlying layer or layers of the III-V compound substrate. The method further comprises transforming the surface charge layer into a passivated surface layer, wherein the passivated surface layer reduces the deleterious performance effect on the underlying layer or layers.

### CROSS-REFERENCE TO CO-PENDING APPLICATIONS

This application is related to co-pending patent application Ser. No. 10/882,482, entitled “Method of Passivating Oxide/Compound Semiconductor Interface,” filed Jun. 30, 2004 (Attorney Docket Number SC13349ZP); Ser. No. (Not yet assigned), entitled “Process of Making A III-V Compound Semiconductor Heterostructure MOSFET,” filed concurrently herewith (Attorney Docket SC13350ZP), and Ser. No. (Not yet assigned), entitled “A III-V Compound Semiconductor Heterostructure MOSFET Device,” filed concurrently herewith (Attorney Docket SC13350ZP PF), all assigned to the assignee of the present disclosures and incorporated herein by reference.

### BACKGROUND

The present disclosures relate to semiconductor structures, and more particularly, to a charge compensated dielectric layer structure and method of making the same.

The existence of charge on gate oxide surfaces presents a problem in certain types of semiconductor devices, in particular, implant free MOSFETs. Examples of implant free MOSFETs are discussed in a co-pending patent application Ser. No. 10/339,379, entitled “An Enhancement mode Metal-Oxide-Semiconductor Field Effect Transistor” filed Jan. 9, 2003 (Attorney Docket Number JG00837) and are not discussed further here. The existence of charge on gate oxide surfaces may not affect the workfunction of a gate metal of implant free MOSFETs to a large extent if the charge density is not excessively high. However, the existence of charge on gate oxide surfaces causes depletion between the gate and source/drain contacts of the implant free MOSFETs. Such depletion causes excessive sheet resistance in an underlying semiconductor layer and degraded device performance, both of which are undesirable.

FIG. 1 is a cross-sectional view of a semiconductor structure 10 having an insulator surface charge layer according to the prior art. Semiconductor structure 10 includes a substrate 12, an insulator layer 14, and an insulator surface charge layer 16. It has been found that for metal-insulator-semiconductor (MIS) structures such as shown in FIG. 1, a substantial amount of charge is trapped in the insulator surface charge layer 16 located on the surface of the insulator layer 14. The insulator surface charge layer 16 may be of similar or identical composition compared to the bulk of the insulator layer 14. It is the large amount of charge trapped in the insulator surface charge layer 16 which substantially increases the sheet resistivity of the MIS structure beyond a value of what is acceptable for device applications.

FIG. 2 is a cross-sectional view of another semiconductor structure 18 having an insulator surface charge layer according to the prior art. Semiconductor structure 18 includes a substrate 12, an epitaxial layer 20, an insulator layer 14, and an insulator surface charge layer 16. It has been further found that for GaAs based metal-oxide-semiconductor (MOS) epitaxial layer structures as shown in FIG. 2, a substantial amount of charge is trapped in the insulator surface charge layer 16 located on the surface of the insulator layer 14, wherein the insulator layer 14 can comprise a gate oxide.

There exists no previously known solution to the issue of insulator surface charge as discussed herein. Neither has an insulator passivated surface layer previously been known as is discussed herein.

Accordingly, there is a need for an improved method and apparatus for overcoming the problems in the art as discussed above.

### BRIEF DESCRIPTION OF THE DRAWINGS

The present invention is illustrated by way of example and not limited by the accompanying figures, in which like references indicate similar elements, and in which:

FIG. 1 is a cross-sectional view of a semiconductor structure having an insulator surface charge layer according to the prior art;

FIG. 2 is a cross-sectional view of another semiconductor structure having an insulator surface charge layer according to the prior art;

FIG. 3 is a cross-sectional view of a semiconductor structure during a processing portion of a method according to one embodiment of the present disclosure;

FIG. 4 is a cross-sectional view of an improved semiconductor structure having an insulator passivated surface layer according to one embodiment of the present disclosure;

FIG. 5 is a graphical representation view of sheet resistivity of various implant free, GaAs based MOSFET structures versus process steps according to the embodiments of the present disclosure;

FIG. 6 is a cross-sectional view of a semiconductor structure formed by a method according to another embodiment of the present disclosure; and

FIG. 7 is a cross-sectional view of a semiconductor structure formed by a method according to yet another embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

According to one embodiment of the present disclosure, a method of forming a charge compensated dielectric layer structure includes removing charge from an insulator surface by one of (i) forming an insulator passivated surface layer positioned on top of an insulator layer or (ii) forming an insulator passivated surface layer positioned in between an insulator layer and a dielectric cap layer, wherein the insulator layer can comprise a gate oxide. According to another embodiment, a semiconductor device comprises a charge compensated dielectric layer structure formed by the above method.

The method and structure of the embodiments of the present disclosure provide several advantages. For example, the method and structure substantially eliminate depletion effects in between the gate and source/drain contacts of an implant free MOSFET device. The method and structure further provide for reducing the sheet resistivity of an underlying semiconductor layer to levels acceptable for implant free MOSFET device applications.

The method and structure according to the embodiments of the present disclosure can be used advantageously in a variety of RF and mixed signal semiconductor circuits. For example, the charge compensated dielectric layer structure can be used in mobile products, such as handsets or wireless local area network (WLAN) type applications. The embodiments of the present disclosure may also be used for heterointegration type applications.

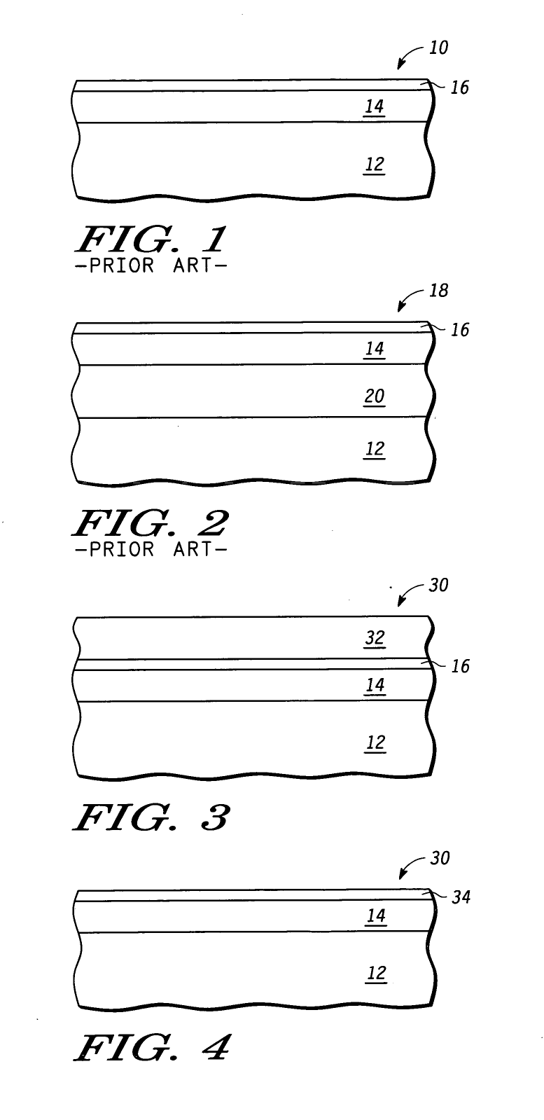

FIG. 3 is a cross-sectional view of a semiconductor structure 30 during a processing portion of a method according to one embodiment of the present disclosure. In this embodiment, semiconductor structure 30 initially includes a substrate 12, an insulator layer 14, and an insulator surface charge layer 16, wherein the insulator surface charge layer 16 contains a substantial amount of trapped charge and thereby having a deleterious performance effect on the underlying semiconductor layer or layers by reducing the amount of mobile charge available in such layers. Layer 16 could also incorporate deleterious stress or strain effects which also could reduce the amount of mobile charge available in the underlying layer or layers. In one embodiment, substrate 12 comprises a III-V compound semiconductor substrate with one or more layers of III-V material epitaxially formed on an upper surface thereof (not shown). For purposes of this disclosure, the substrate and any epitaxial layers formed thereon will be referred to simply as a compound semiconductor substrate.

As discussed herein, one or more process steps are used to passivate charge sitting on a surface layer. In a semiconductor structure, delta doping (δ-doping) provides a source of electrons (e⁻). In addition, sheet resistivity (sheet rho) can be expressed as the quantity 1/(nₛ μ q), where nₛ is sheet carrier density, μ is charge carrier mobility, and q is unit charge. As mentioned, it is desired that the charge on the surface layer be zero. Accordingly, the sheet carrier density (nₛ) is made to be approximately equal to the δ-doping.

Semiconductor structure 30 is then processed by the coating the insulator surface charge layer 16 with a temporary cap layer 32. In one embodiment, the temporary cap layer 32 includes an optical photoresist. For example, the optical photoresist may comprise commercially available AZ6210PRMIF manufactured by AZ Electronic Materials, 70 Meister Avenue, Somerville, N.J. 08876 USA or other similar type photoresist. Subsequent to coating the insulator surface charge layer 16 with temporary cap layer 32, the semiconductor structure 30 is subjected to a suitable curing step, such as a furnace bake, according to the particular requirements of the particular temporary cap layer material. In one embodiment, the semiconductor structure 30 is subjected to a suitable photoresist curing step, such as a furnace bake, according to the particular requirements of the photoresist.

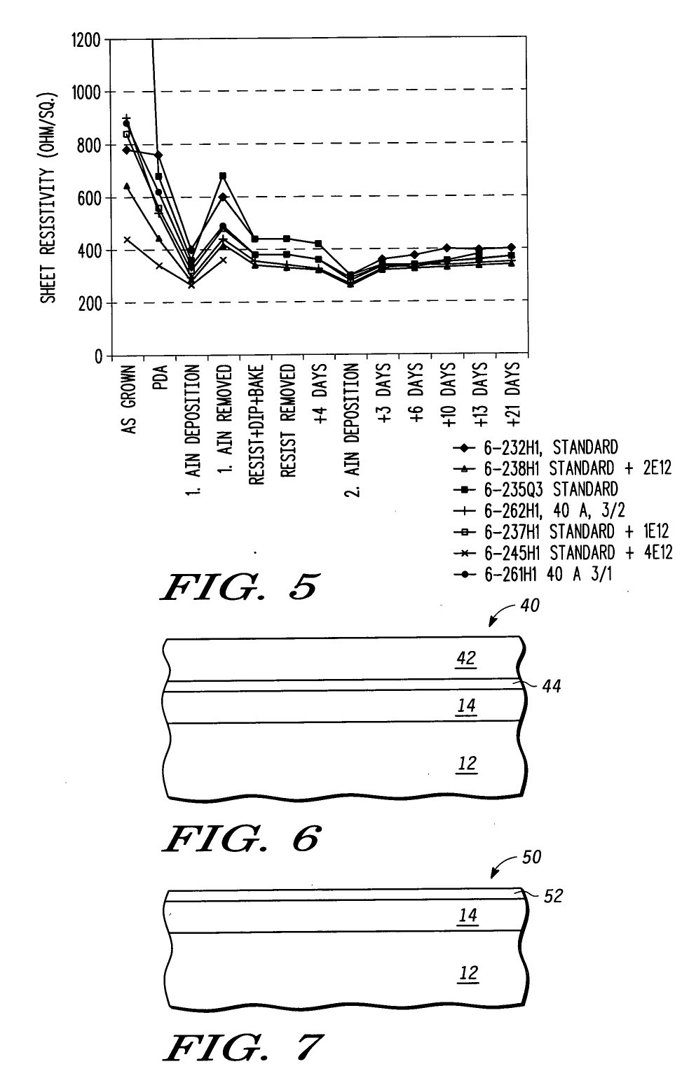

FIG. 4 is a cross-sectional view of an improved semiconductor structure having an insulator passivated surface layer according to one embodiment of the present disclosure. During the process of (i) coating the insulator surface charge layer 16 with the photoresist 32, (ii) the subsequent processing of the photoresist and (iii) its removal, layer 16 is transformed into an insulator passivated surface layer 34. Insulator passivated surface layer 34 is substantially free of trapped charge and thus reduces the sheet resistivity of the underlying compound semiconductor substrate. Accordingly, subsequent to the coating and curing of the photoresist 32, the method continues with the removal of the cured photoresist. It is noted that in any given semiconductor manufacturing process, prior to removal of a cured photoresist, additional processing steps may occur, for example, the cured photoresist may then be subjected to exposure and development process steps, followed by etching, additional depositions, etc., according to the requirements of a particular integrated circuit or semiconductor device manufacturing process.

In an alternate embodiment, subsequent to the PR coating and prior to the curing or bake step, the semiconductor structure 30 is subjected to a developer dip. The developer dip can include for example, commercially available developer AZ527MIF manufactured by AZ Electronic Materials, 70 Meister Avenue, Somerville, N.J. 08876 USA. Subjecting the PR coated structure to the developer dip prior to the curing step may reduce any remaining amount of trapped charge in the insulator passivated surface layer 34 even further than the process without using the developer dip.

FIG. 5 is a graphical representation view of sheet resistivity of various implant free, GaAs based MOSFET structures versus process steps according to the embodiments of the present disclosure. The as-grown GaAs based MOSFET structure comprises a GdGaO dielectric stack deposited onto GaAs based epitaxial layers. The target sheet resistivity is 400-500 Ohm/sq.

FIG. 5 shows the sheet resistivity of MOSFET wafers as grown, subjected to a post deposition annealing step (PDA), a first AlN cap layer deposition and subsequent removal, a standard photoresist module, and a second AlN cap layer deposition. The AlN film is done by sputter deposition, the subsequent AlN removal uses MF24a developer. The standard photoresist module includes a photoresist coat (AZ6210), a dip (AZ527), and a bake (135° C., 45 sec). Photoresist removal is accomplished by acetone and isopropanol. The PDA step includes water vapor annealing, as discussed in co-pending patent application Ser. No. 10/882,482, entitled “Method of Passivating Oxide/Compound Semiconductor Interface,” filed Jun. 30, 2004 (Attorney Docket Number SC13349ZP), incorporated herein by reference, and is not discussed further here.

After the step of “1. AlN cap layer deposition,” the sheet resistivity of all the MOSFET wafers shown falls to 300-400 Ω/sq independent of AlN cap layer thickness investigated (10-100 nm). When the AlN cap layer is subsequently removed, the sheet resistivity increases and only remains slightly below the values measured before the step of “1. AlN cap layer deposition.”

With respect to the AlN cap layer deposition, the measured sheet resistivity confirms that an AlN cap layer creates an insulator passivated surface layer. However, this insulator passivated surface layer is essentially removed when the AlN cap layer is removed. During the process of AlN cap layer deposition, the insulator surface charge layer is transformed into an insulator passivated surface layer. The insulator passivated surface layer is substantially free of trapped charge and thus reduces the sheet resistivity of the underlying compound semiconductor substrate. An alternative explanation for the drop in sheet resistivity after AlN cap layer deposition is that the presence of the AlN cap layer significantly lowers surface tension of the insulator layer.

Subsequent to AlN cap layer removal, a standard photoresist module is used including coating, dip, and bake. Note that the photoresist coating also constitutes a “cap layer” in the context of this disclosure. After completion of the photo module, the sheet resistivity falls to values in the range of 300-400 Ω/sq. Even after photoresist (cap layer) removal, the surface passivation effect persists. It was found by ellipsometry that a thin layer (1 nm) remained on the gate oxide surface after photoresist (cap layer) removal. Again, “surface charge removal” and “lowering of surface tension”, either one potentially caused by the presence of an insulator passivated surface layer, are possible underlying mechanisms. It was also found that “vapor prime” alone, a bake step (≅100° C.) to promote photoresist adhesion, lowers MOSFET sheet resistivity into a range similar to that observed after photoresist coating/dip/bake. It is believed that “vapor prime” also creates a thin surface layer which acts as an insulator passivated surface layer

According to the embodiments of the present disclosure, the applicants discovered, contrary to expectations, that the charge that had been located and trapped in the insulator surface charge layer can be essentially removed. In one embodiment, the charge located and trapped in the insulator surface charge layer is substantially completely removed by applying a prescribed cap layer or layers, such as AlN, to the insulator surface charge layer. Application of the prescribed cap layer or layers creates an insulator passivated surface layer in place of the previous insulator surface charge layer. Accordingly, the insulator passivated surface layer reduces the sheet resistivity of the underlying epitaxial layer structure to sheet resistivity values that are acceptable for device applications, for example, implant free MOSFET device applications.

The applicants further discovered, contrary to expectations, that other prescribed cap layers, such as SiO₂, increase the charge trapped in the insulator surface charge layer. As a result, such other prescribed cap layers are not useful for creating an insulator passivated surface layer. A summary of sheet resistivity data for various dielectric layer structures is presented in Table 1 below. As indicated by the data of Table 1, a number of wafers were provided with two or more dielectric layer structures. For the GdGaO layer, the gate oxide surface is exposed to air. For the AlN/GdGaO dielectric layer structure and the SiO₂/GdGaO gate dielectric layer structure, the surface of GdGaO was capped with AlN and SiO₂, respectively. All data was obtained post deposition annealing step (PDA), and further obtained via eddy current measurements (Sonogage) in room light. The presence of the AlN capping layer resulted in an approximate fifty-percent (50%) or more reduction in the sheet resistivity compared to the air exposed GdGaO surface transforming the insulator surface charge layer into an insulator passivated surface layer. The presence of the SiO₂ capping layer, on the other hand, clearly increased the charge trapped in the insulator surface charge layer by an order of magnitude or greater compared to the GdGaO surface without the presence of the SiO₂ capping layer.

TABLE 1

| | Dielectric | Sheet Resistivity (Ohm/sq.) | |
|---|---|---|---|
| | Layer | Gate Oxide Surface | |
| Wafer No. | Structure | Exposed to Air | GdGaO Surface Capped |
| 6-169 | GdGaO | 910-930 | |
| | AlN/GdGaO | | 481 |
| | SiO₂/GdGaO | | 8290 |
| 6-173 | GdGaO | 1260 | |
| | AlN/GdGaO | | 602 |
| 6-174 | GdGaO | 1190-1240 | |
| | AlN/GdGaO | | 571 |
| | SiO₂/GdGaO | | 2120 |
| 6-179 | GdGaO | 1510 | |
| | AlN/GdGaO | | 688 |
| 6-180 | GdGaO | 1170 | |
| | AlN/GdGaO | | 625 |

FIG. 6 is a cross-sectional view of a semiconductor structure formed by a method according to another embodiment of the present disclosure. In this embodiment, semiconductor structure 40 initially includes a substrate 12, an insulator layer 14, and an insulator surface charge layer 16. Semiconductor structure 40 is then processed by forming a cap layer 42 on the insulator surface charge layer 16. In one embodiment, cap layer 42 can include any suitable material(s), for example, AlN, that causes a transformation of the underlying insulator surface charge layer 16 into an insulator passivated surface layer 44. In contrast, other materials, such as SiO₂, are not suitable for transforming the underlying insulator surface charge layer 16, but rather, further add undesirably to the surface charge.

FIG. 7 is a cross-sectional view of a semiconductor structure formed by a method according to yet another embodiment of the present disclosure. In this embodiment, semiconductor structure 50 initially includes a substrate 12, an insulator layer 14, and an insulator surface charge layer 16. Semiconductor structure 50 is then processed by a vapor prime step. In one embodiment, the vapor prime step includes exposing the insulator surface charge layer 16 to a vapor prime with use of Hexamethyldisilazane (HMDS) in the gas phase. In one embodiment, the vapor prime formula comprises C₆H₁₉NSi₂. In one embodiment, the vapor prime comprises exposing the surface layer to a temperature on the order of 100-150 degrees Celsius in an ambient suitable for facilitating photoresist adhesion. During the vapor prime step, the insulator surface charge layer 16 is transformed into an insulator passivated surface layer 52.

In the foregoing specification, the disclosure has been described in reference to the various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the present embodiments can apply to semiconductor device technologies where minimal surface charge is crucial to device performance.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of forming a semiconductor structure comprising:
providing an insulator layer overlying a substrate, the insulator layer having a surface charge layer, the surface charge layer having a deleterious performance effect on the underlying layer or layers; and
transforming the surface charge layer into a passivated surface layer, wherein the passivated surface layer reduces the deleterious performance effect on the underlying layer or layers.

2. The method of claim 1, wherein transforming said surface charge layer includes coating with a photo-resist (PR), curing the PR, and removing the cured PR.

3. The method of claim 1, wherein transforming said surface charge layer includes forming a cap layer overlying said surface charge layer.

4. The method of claim 3, further wherein the cap layer includes an aluminum nitride layer.

5. The method of claim 1, wherein transforming said surface charge layer includes exposing the surface charge layer to a vapor prime.

6. The method of claim 5, further wherein the vapor prime comprises exposing the surface charge layer to a temperature on the order of 100 degrees Celsius in an ambient suitable for facilitating photoresist adhesion.

7. The method of claim 5, wherein the vapor prime comprises use of Hexamethyldisilazane (HMDS) in the gas phase.

8. The method of claim 5, wherein the vapor prime comprises C₆H₁₉NSi₂.

9. The method of claim 1, wherein the insulator layer comprises an oxide layer.

10. The method of claim 1, wherein the semiconductor structure comprises a III-V compound structure and the substrate comprises a III-V compound substrate.

11. A method of forming a semiconductor structure comprising:
providing an insulator layer overlying a substrate, the insulator layer having a surface charge layer, the surface charge layer having a deleterious performance effect on the underlying layer or layers; and
transforming the surface charge layer into a passivated surface layer, wherein the passivated surface layer reduces the deleterious performance effect on the underlying layer or layers and wherein transforming said surface charge layer includes one or more of (i) coating the surface charge layer with a photo-resist (PR), curing the PR, and removing the cured PR, (ii) forming a cap layer overlying said surface charge layer, and (iii) exposing the surface charge layer to a vapor prime.

12. The method of claim 11, further wherein the cap layer includes an aluminum nitride layer.

13. The method of claim 11, further wherein the vapor prime comprises exposing the surface charge layer to a temperature on the order of 100 degrees Celsius in an ambient suitable for facilitating photoresist adhesion.

14. The method of claim 11, wherein the vapor prime comprises use of Hexamethyldisilazane (HMDS) in the gas phase.

15. The method of claim 11, wherein the vapor prime comprises C₆H₁₉NSi₂.

16. The method of claim 11, wherein the insulator layer comprises an oxide layer.

17. The method of claim 11, wherein the semiconductor structure comprises a III-V compound structure and the substrate comprises a III-V compound substrate.

18. A semiconductor structure having an insulator layer overlying a substrate, the insulator layer having a passivated surface layer formed by the method of claim 11.

19. A compound III-V semiconductor structure having an insulator layer overlying a compound III-V substrate, the insulator layer having a passivated surface layer formed by the method of claim 11.

20. A compound III-V semiconductor structure having an insulator layer overlying a compound III-V substrate, the insulator layer having a passivated surface layer formed by the method of claim 1.
